(19) United States
(12) Patent Application Publication
(10) Pub. No.: US 2021/0294940 A1
(43) Pub. Date: Sep. 23, 2021

(54) SYSTEM, APPARATUS, AND METHOD FOR SIMULATING THE VALUE OF A PRODUCT IDEA

(71) Applicant: Conor Haas Dodd, Ypsilanti, MI (US)

(72) Inventor: Conor Haas Dodd, Ypsilanti, MI (US)

(21) Appl. No.: 16/949,842

(22) Filed: Nov. 17, 2020

Related U.S. Application Data
(60) Provisional application No. 62/911,628, filed on Oct. 7, 2019.

(51) Int. Cl. G06F 30/20; G06F 30/12; G06F 3/0482

(52) U.S. Cl. CPC G06F 30/20; G06N 5/003; G06F 3/0482; G06F 30/12

(57) ABSTRACT

A system, apparatus, method, and computer program product that allows a user to simulate the value of a product idea and reduces the time and skills required to evaluate an idea's market potential. Aspects of the present invention include: a user interface; a Model Builder/Guidance Engine; a Simulation Engine; and a Results/Feedback Engine.

### CROSS-REFERENCE TO RELATED APPLICATION

This application claims the benefit of priority of U.S. provisional application No. 62/911,628, filed Oct. 7, 2019, the contents of which are herein incorporated by reference.

### BACKGROUND OF THE INVENTION

The present invention relates to invention development, and more particularly to evaluating value of a product idea.

Inventors who are pursuing new ideas often struggle to assign market value to those ideas at an early stage. This is especially true when the effects of the idea may be complex or nuanced. This leads to many ideas getting rejected, either by the inventor or the inventor's employer, without truly knowing if the idea has merit.

A traditional market study is often either too costly to be justified at early stage, or requires special skills which the inventor may not possess.

As can be seen, there is a need for improved systems, apparatus, and methods to reduce the time and skills required to evaluate an invention's market potential.

### SUMMARY OF THE INVENTION

In one aspect of the present invention, a system for simulating attributes of an invention. The system includes a model builder engine configured with a plurality of user controls to input a plurality of parameters to define a model of the invention. A simulation engine is configured to dynamically test the model in a simulation against a plurality of simulated actors in a virtual world according to the plurality of parameters defined in the model of the invention. A results engine is configured to processes a result of the simulation and extract useful data for displaying one or more attributes of the invention.

In some embodiments, a guidance engine is configured to provide a feedback to the user on one or more qualities of the model to set one or more of the plurality of parameters defining the model of the invention.

In some embodiments, the guidance engine includes an actor definition control comprising a selector for choosing one or more of a plurality of preset actors defined according to a plurality of predefined demographic groups, specifying a target user of the invention. The demographic groups are specified according to one or more of a geographic location, a gender, an income, and an age. The simulation steps the actors through a decision model, within the model of the invention.

In some embodiments, a quality summary page is configured to provide the user a rating of the user's selections for each of the model design, the actor selection, and the one or more simulation parameters.

In some embodiments, the guidance engine provides one or more hints for improving a performance of one or more of the model designs, the actor selection, and the one or more simulation parameters.

In some embodiments, the simulation engine processes a passive simulation in which the attributes of the invention processed by the simulation are compared with the simulation in the absence of the invention.

In other embodiments, the simulation engine processes an active simulation in which the attributes of the invention processed by the simulation are compared with an actor option to utilize the invention or a competitor invention.

In other embodiments, the model builder engine includes a plurality of controls are operable by the user to define a function, an item, a relation, and a space.

In yet other embodiments, the results engine produces a display indicating a number of simulants who use the product; one or more common traits of the simulants who use the product; and one or more most-used competitors.

These and other features, aspects and advantages of the present invention will become better understood with reference to the following drawings, description and claims.

### BRIEF DESCRIPTION OF THE DRAWINGS

FIG. 1 is a depiction of a model builder engine user interface screen.

FIG. 2 is a depiction of a first guidance engine user interface screen.

FIG. 3 is a depiction of an actor selection user interface screen.

FIG. 4 is a depiction of a quality summary user interface screen.

FIG. 5 is a depiction of a simulation results user interface screen.

FIG. 6 is a depiction of an investor user interface screen.

FIG. 7 is a depiction of a first management user interface screen.

FIG. 8 is a depiction of a second management user interface screen.

FIG. 9 is a schematic view of a comparative definition of an invention.

FIG. 10 is a schematic view of a complex value stream model.

FIG. 11 is a schematic view of the invention.

FIG. 12 is a schematic view of the RA economy.

FIG. 13 is a schematic view of a decision model.

FIG. 14 is a schematic view of a decision model.

FIG. 15 is a schematic view of graphed results.

FIG. 16 is a schematic view of generic function.

FIG. 17 is a schematic view of decision model for an app-based purchasing model.

FIG. 18 is a schematic view of decision model for an excavator shovel.

FIG. 19 is a schematic view of decision model for a light rail transit (LRT) system.

FIG. 20 is a schematic view of a belief-desire-intent model.

FIG. 21 is a schematic view of a larger decision tree.

### DETAILED DESCRIPTION OF THE INVENTION

The following detailed description is of the best currently contemplated modes of carrying out exemplary embodiments of the invention. The description is not to be taken in a limiting sense, but is made merely for the purpose of illustrating the general principles of the invention, since the scope of the invention is best defined by the appended claims.

Broadly, embodiments of the present invention provide a system, method, apparatus, and computer program product for evaluating an invention's market potential. As stated above, inventors who are pursuing new ideas often struggle to assign market value to those ideas at an early stage, especially when the effects of the idea may be complex or nuanced. This leads to many ideas getting rejected either by the inventor or the inventor's employer without truly knowing if the idea has merit.

In one aspect of the invention a computer program product software provides a graphical user interface (GUI) for the inventor or other user to create a model of their inventive idea. That model can be tested in a simulated environment where virtual actors may use or not use the inventive idea. The value of the inventive idea can then be estimated based on the effect of the invention idea on the virtual actors. The software contains guides to assist the user in creating an accurate model and correctly interpreting the results of the simulation.

The system of the present invention provides a simple formal method for evaluating early stage invention ideas, reducing the cost of either rejecting good ideas, or pursuing bad ones. The present invention provides a standard model format which makes it easy to share descriptions of an item or process. This model format can be used by a cloud-based sharing service to allow inventors to compare models and pitch their idea to investors.

Aspects of the present invention include: a User Interface 10; a Model Builder Engine 20; a Guidance Engine 30; a Simulation Engine 40; and a Results/Feedback Engine 50. In some embodiments, an investor module 60 is provided to allow one or more investors to view inventions and allow for investment in the invention. In other embodiments, a management module 70 provides oversight of a plurality of inventions in the system.

The user interface provides the interface between the user and the computer program software and allows the user to navigate their way among the various components of the application. The user interface includes one or more pages displayed on the screen of a computing device. The user interface sends user input and receives data back from the model builder engine 20, the guidance engine 30, the simulation engine 40, and the results feedback engine 50.

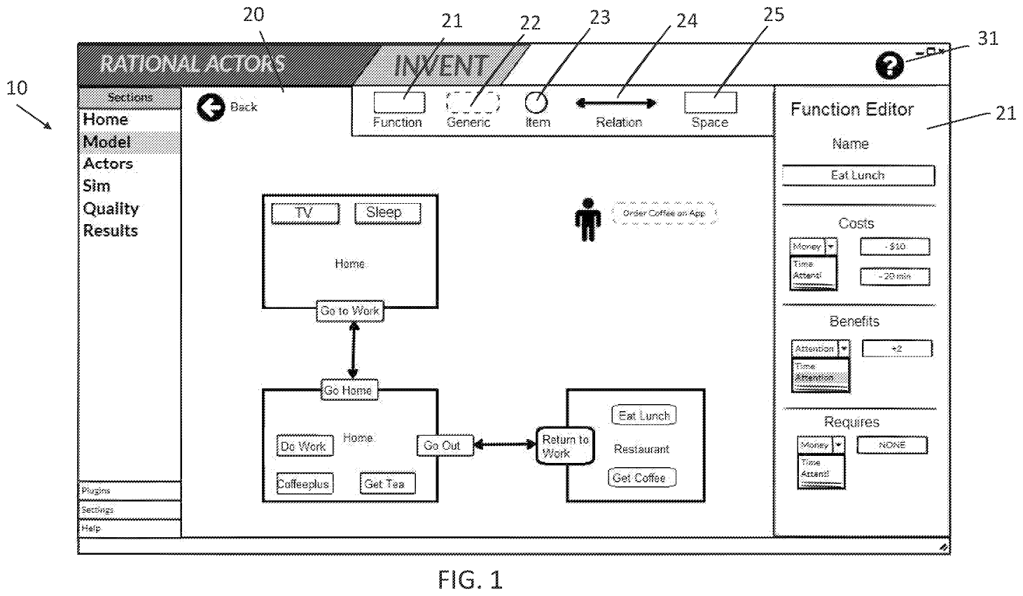

The model builder engine 20 is a software component that allows the user to build a model of the system based on the user input. A non-limiting embodiment of the model builder engine 20 is shown in reference to FIG. 1.

The guidance engine 30 is configured to provide a feedback on the model quality which can be used to provide help to the User define the model of the invention. The model builder engine 20 and the guidance engine 30 send data to a simulation engine 40 in order to run a simulation of the inventive idea.

The simulation engine 40 receives the model from the model builder engine 20 and inputs from the guidance engine 30 and runs the simulation. Once the simulation is complete the results data is sent to the results/feedback engine 50. The results/feedback engine 50 processes the results of the simulation and extracts useful data for one or more attributes of the invention. The data is then sent to the user interface for display to the user.

The user interface 10 provides an easy-to-use graphical interface where a user who is not a coding or marketing expert may create a model of their system. The user interface 10 also provides a way to display results to the user that are easily interpreted, allowing the user to decide what to do with their invention.

As seen in reference to FIG. 1, the model builder engine user interface 20 provides a method to translate the user input into a functional and accurate model. The user interface 20 has a field where the user defines functions and models where those functions become available in a simulated person's world. A plurality of model controls includes a function control 21, a generic placeholder 22, an item 23, a relation 24, and a space 25. Activation of one or more of the plurality of model controls presents a corresponding control editor. The control editor presents the user a plurality of fields, including a name filed to identify the function. For example, a cost field, assists the user to identify a cost associated with the function, which may be a monetary cost, a time cost, or a, or a custom-defined cost, such as removal of specific items or accepting a restriction of future options. The control editor may also include a benefits selector that allows the user to specify a benefit derived from the function. The benefit may be specified in a time savings, an attention, or the like. The user may input a value corresponding to a weighting of the benefit. The control editor may also present a requirements field, where the user may specify one or more resources required for the function.

The generic control 22 may provide a placeholder for the user to capture and present ideas and concepts associated with the model. An item control 23 allows the user to place items associated with the invention in the model. A relation control 24 allows the user to designate relationships between one or more of a function, a n item, and a space associated with the invention. A space control 25 allows the user to define one or more locations at which functions, and items are located within the model. The user interface 10 allows the user to drag and drop the one or more icon representations of the control selections for each of the function, the generic placeholder, the item, the relation, and the space inputs.

The guidance engine 30 may be activated by a guidance control 31 in the user interface 10. Activation of the guidance control 31 presents a project setup menu 32. The project setup menu 32 provides guidance options that the user may select from to facilitate defining their invention. The guidance options may be selected individually, or the user may navigate them sequentially via a directional control, (next and back) to review the guidance options. The user interface presents a plurality of user selectable radio buttons 37 corresponding to a description of a cost, a benefit, a competition, and a finish condition, that most closely corresponds to their invention.

The guidance engine 30 may also include an actor definition interface 26, such as shown in FIG. 3, that permits the user to select a target population of consumers or users of their invention. The actor definition 26 includes a plurality of preset actor characteristics for a plurality of predefined demographic groups 38. The demographic groups may be specified according to geographic location, gender, income, age, and other demographic attributes of a target audience for the invention. The one or more target populations are utilized in running the simulation of the product. The simulation steps the virtual “actors” through their lives (within the simulation), with the actors making decisions along the way. Using a decision making model informed by rationality and behavioral economics, and taking in all factors such as cost and time, actors decide which “toaster” they prefer. Actors may communicate experiences to one another, influencing their decision making.

Decision spaces may be virtual or real. All aspects of an actor's decision making process may be modeled, such as adding possessions, options, or goals for the Actor to strive to achieve.

The guidance engine 30 may also provide a quality summary page 39. The quality summary page provides the user a rating of the user's selections for each of the model design, the actor selection, and simulation parameters. The quality summary page 39 may also provide the user one or more hints for improving one or more of the model designs, the actor selection, and simulation settings to improve the performance of the simulation for the user's invention. This may include: filling in gaps on the User's selection with standard or selectable economic assumptions, providing feedback as to what areas of the model could be improved, optimizing the model for best performance, or setting up a search where multiple configurations may be tested automatically.

The simulation engine 40 runs the models provided to it by the model builder engine 20 and the guidance engine 30. To do so it creates simulated “actors” in a virtual world, the parameters of which are defined in the model received from the model builder 20 and guidance engine 30. The “actors” go through the world making decisions that maximize their happiness among other factors. The “actors” process of decision making is designed to balance accuracy and adherence to human decision-making, and simulation speed, and may be customized. The introduction of the User invention to the simulated world may be passive, (the actors must use the idea, and the effect is compared to a simulation without the idea), or active, (where the “actors” are given the option to purchase the idea or use a competitor). In this way the objective of each simulation can be customized.

The results/feedback engine 50 interprets the results of the simulation and generates useful feedback for the user. This feedback may include (but is not limited to): The effect of the idea on the simulated world, the number or “actors” who use or purchase the idea, the properties of the “actors” (income, security, hunger, etc.), that result in an “actor” being statistically likely or unlikely to buy the idea. Numerous standard logical processes will take place within the four software components.

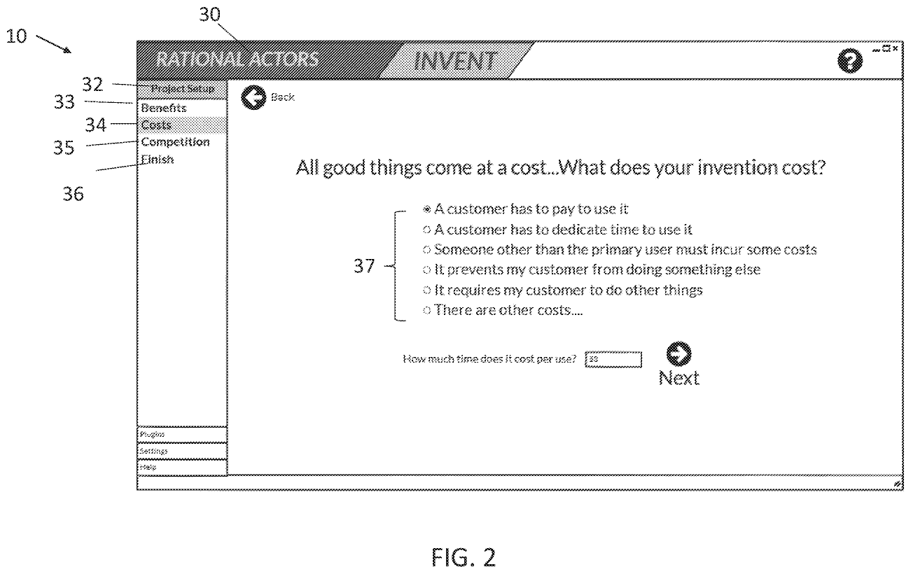

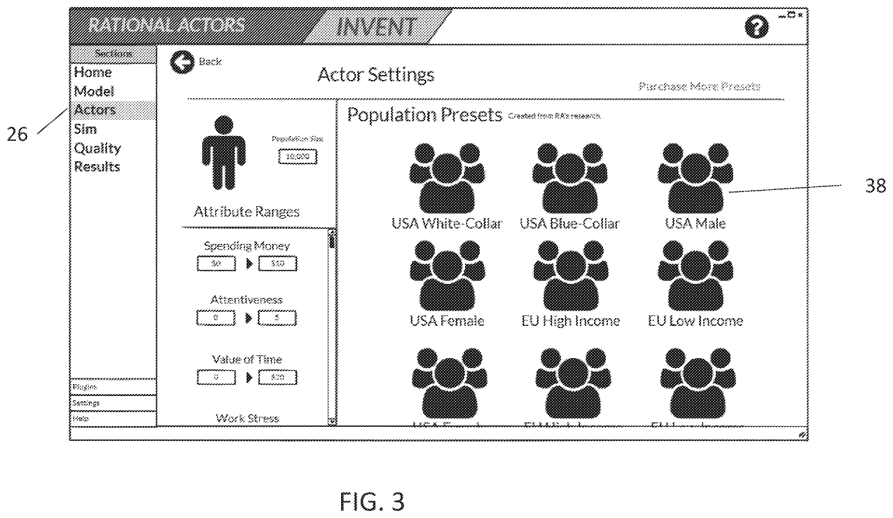

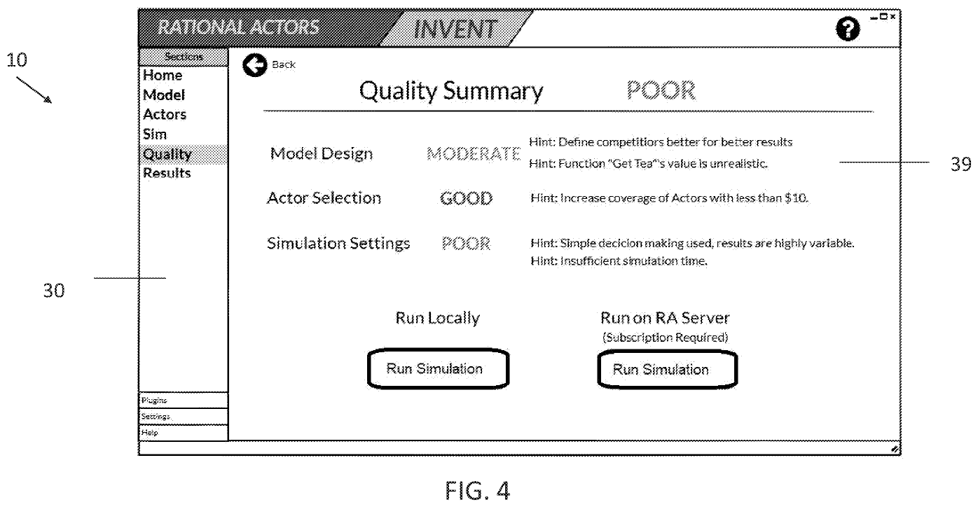

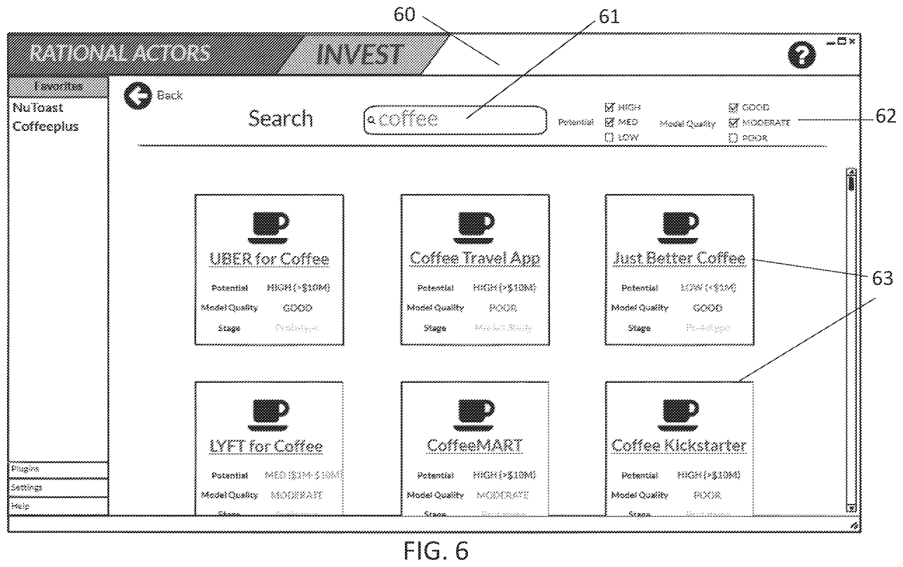

As seen in reference to the drawings of FIGS. 1-7, the user starts by having an idea for a product or invention, one that they would like to develop further if there is market potential. They access the software through their PC, smartphone, or similar device. In the software they use simple modelling tools to create a representation of a world in which their idea exists. During this process the software may give the user feedback on how to improve their model.

The user determines whether they would like to study the effect of their invention alone, test whether people will buy the invention at a certain price, or explore many different prices and personal preferences to find an optimum solution.

Once the model is complete the user selects to run the simulation engine 40. The simulation engine 40 runs a simulation of the invention based on the inputs selected. In some embodiments, the simulation engine 40 provides real-time status information back to the user. Once the simulation is complete the software compiles the data from the simulation, extracting useful metrics such as performance over time, the personal qualities most likely to result in a purchase, an ideal price, and other useful components of valuation.

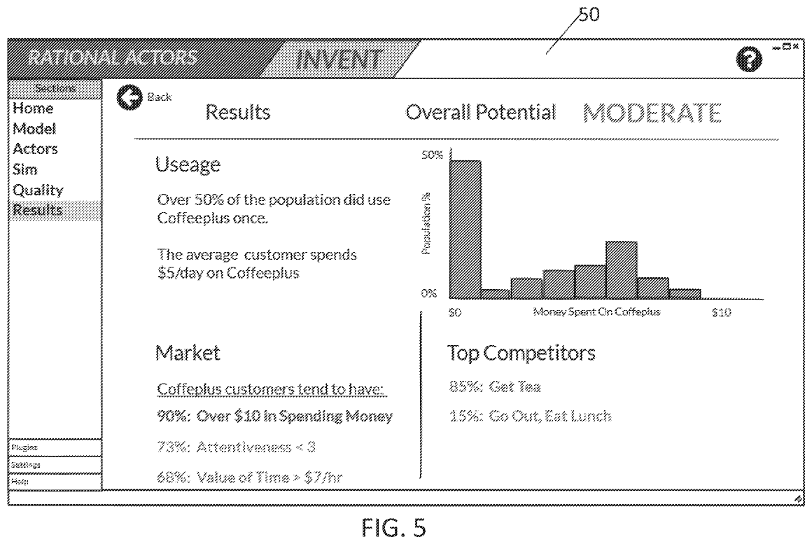

The information derived from the simulation engine 40 is then displayed to the user in a simulation results interface 50, such as shown in FIG. 5. The simulation results 50 may include a number of simulants who use the product; one or more common traits of those who use the product; one or more most-used competitors. The simulation engine 40 is configured to capture any information that can be mined from observing simulant behavior during the simulation.

By navigating the user interface 10, users can go back to earlier stages in the process, refine their models or product properties, and run simulations to try and achieve better results. The user may save their model for later reference, or share their model on a cloud serve in order to receive feedback from other users or investors.

An investor interface 60 may be provided to allow investors to assess potential inventions hosted by the platform. The investor interface may include a search window 61 to locate an invention of interest to the investor. The search window may be augmented by one or more properties 62 assigned to the invention, such as a potential and a grading of the model quality. The investor may select from one or more projects 63. Selection of a project 63 allows the investor to view the detailed model, review assumptions and model issues. The investor may also be able to contact the inventor for more information pertaining to the invention.

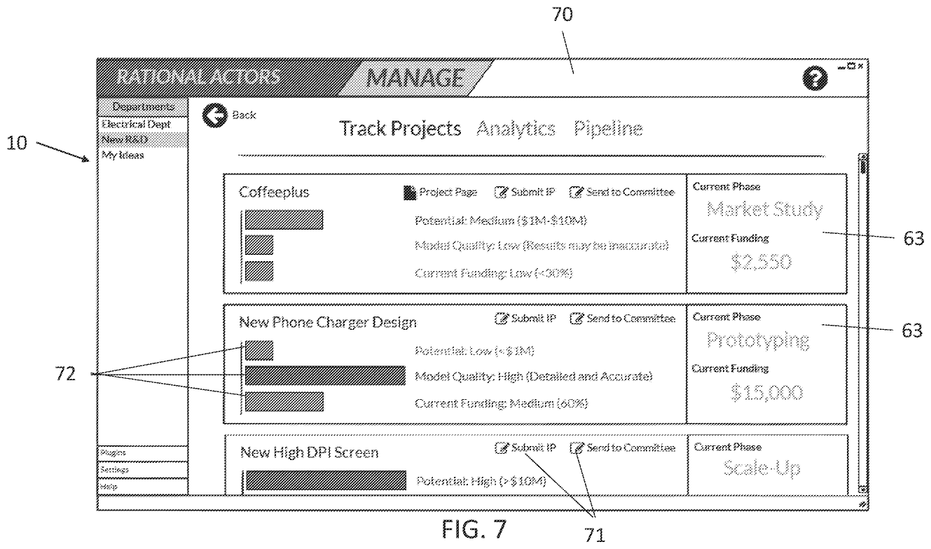

A management interface 70, such as shown in FIG. 7, may be provided to allow individuals or organizations with multiple ongoing projects to track their status and modelling results using the software interface. The management interface 70 may include a listing of the one or more projects 63. The management interface 70 presents tracking information for the one or more projects 63. The tracking information may include one or more selectors 71 for indicating a progress of the project in a product development cycle. The management interface 70 may also provide a graphical and/or textual representation 72 of each of a potential, model quality, and a funding progress indicator.

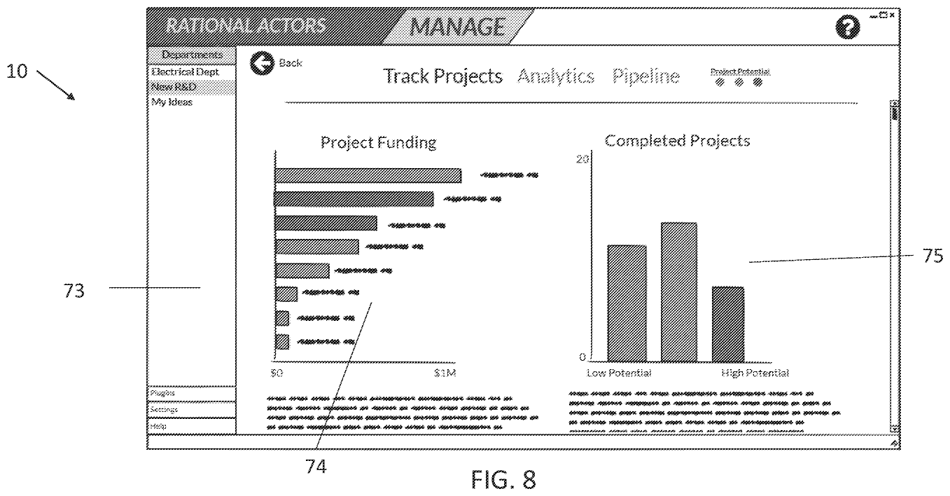

As seen in FIG. 8, the management interface 70 may also include a portfolio view 73 which presents aggregated data for a plurality of projects 63. The portfolio view 73 may include a project funding tracker 74 showing progress of a funding stream for the plurality of projects 63. The management interface 70 may also include a completed projects summary 75 showing a compilation of a plurality of completed projects for the organization. By way of non-limiting example, the completed projects summary 75 may include a representation of a project potential for the plurality of completed projects.

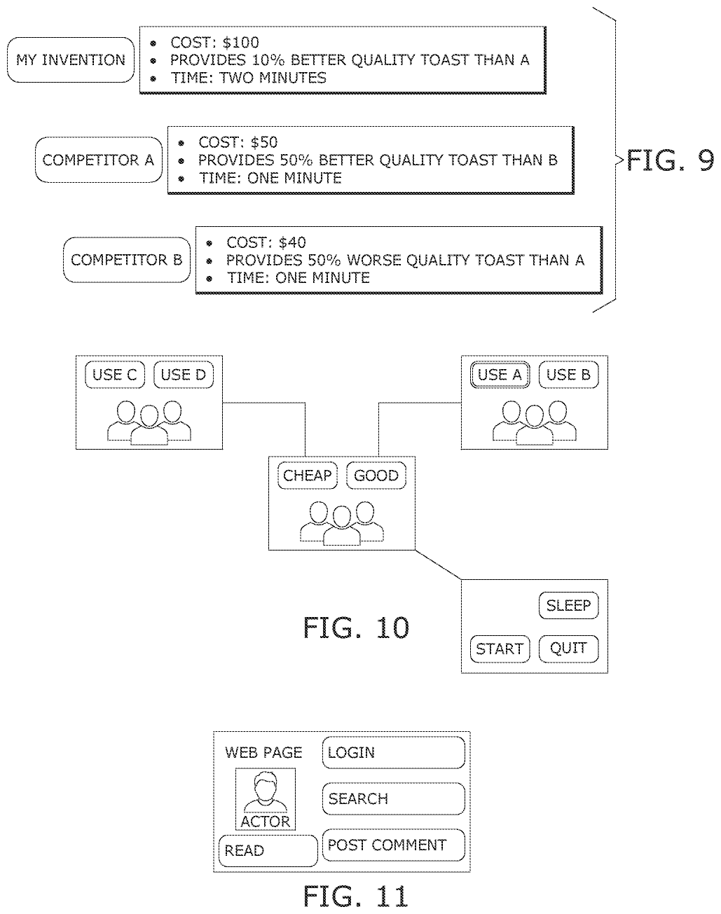

The simulation engine 40 is configured to simulate operation of the invention model. The model definition allows against a plurality of market factors and a plurality of behavior factors defined in the invention model. As shown in FIG. 9, the plurality of market factors may include a simulation of the invention against one or more competitive products. The comparison may include assessment of both quantitative and qualitative factors. By way of non-limiting example, the model may define a comparison cost, a quality, and a performance metric. In the example shown, the invention is a toaster. The quantitative factors include a cost of the toaster and a completion time in which the toaster produces a toast. The qualitative factor may include a relative assessment of the toast as compared the competitive toasters.

FIG. 10 is a schematic view of a complex value stream that may be defined in the model builder engine 20. The complex value stream definition models decision points where a simulant (also referred to as “actors”) must choose between available options. Simulants are virtual decision-makers who are defined with a set of needs as shown in FIG. 16. These needs may be custom-defined by the user, pulled from demographic data, identified based of the model setup by the guidance engine 30, or assigned randomly by the simulation. Needs may be weighted based on priority, may be assigned automatic decay or rise rates, or may be tied to events, such as the actor obtaining possession of an item or completing a task. Tasks are defined as actions the simulant performs which directly or indirectly alter the status of the simulant's needs. The costs and benefits of a task are defined as the effects the task has on the simulant's needs. Examples may include: A “Buy Soda” task which fulfills a simulant's “Thirst” and “Sugar” needs but reduces their “Gain Money” need, a “Trade” task which fulfills their need to obtain item “A” at the cost of removing item “B” from their possession, or a “Travel to park” task which negatively impacts a simulant's need for “Leisure time” while simultaneously opening up the ability to choose between various park tasks once the travel task is completed. Such properties of needs and tasks are customizable by the user when the model is defined.

During the simulation the simulants behave as rational economic actors, choosing from the tasks available the option that results in maximum satisfaction of their needs according to a Belief-Desire-Intent Model (FIG. 13). The user may customize the simulant behavior to introduce irrational decision-making properties if desired.

The model displays options as discrete-events, at each point in time simulant chooses an option from the list available to it in the given decision space. Options may, as part of their defined effects, move the simulant to another decision space where other options are available. Decision spaces may represent physical locations, such as a room with multiple doors, or be purely logical, such as deciding whether or not to play tennis based on a tree of sub-choices. FIG. 11 provides an example where a webpage presented to the user represents a simulated decision space, where a simulated user must choose which link to click on the page from the decisions available.

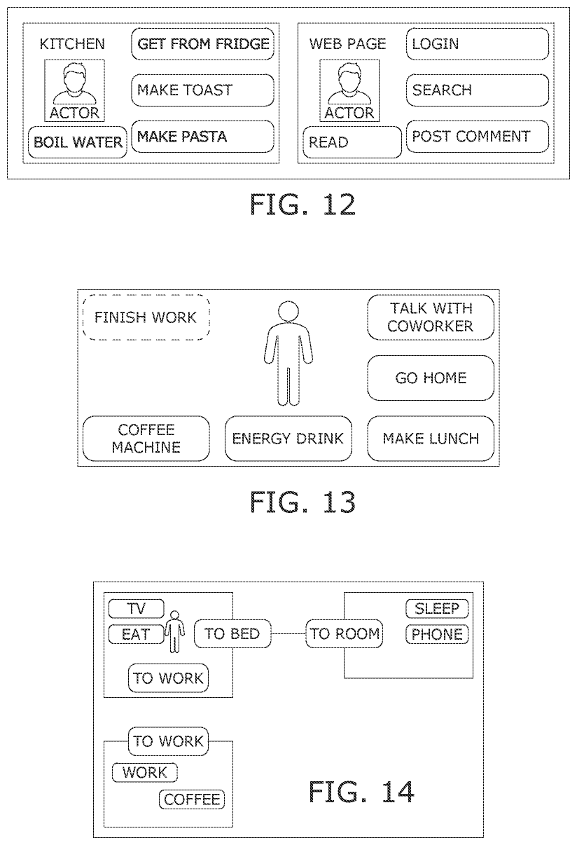

FIG. 12 is a schematic view of the Rational Actors economy where a plurality of users can share and adapt existing models for their inventions. A plurality of specialized tools makes evaluation of certain inventions easier. The plurality of specialized tools may include a branding toolbox, a home appliance toolbox, a software toolbox, and a crowd communication toolbox.

FIG. 13 is a schematic view of a decision model created with the model builder engine 20. The model defines the world the invention occupies. Rather than a physical space, the world the actor occupies is a series of decisions. A decision is when an actor must choose between available functions. A Decision Space doesn't need to be anything real, for example, it can be a webpage where the user must choose a link, or simply a time in the actor's life where it must choose a path. In the model of FIG. 13, there are 3 competitive functions.

FIG. 14 is a schematic view of a decision model, Actors make decisions one at a time, jumping from space to space if applicable. For example, an advanced coffee machine model would include a desire for Entertainment, which would be fulfilled by TV or Phone. The use of Coffee at work, allowing work to be completed faster, allows the actor to spend more time on entertainment. Each representing a series of decisions. The more complete the model, the better the analysis of all the invention's side effects.

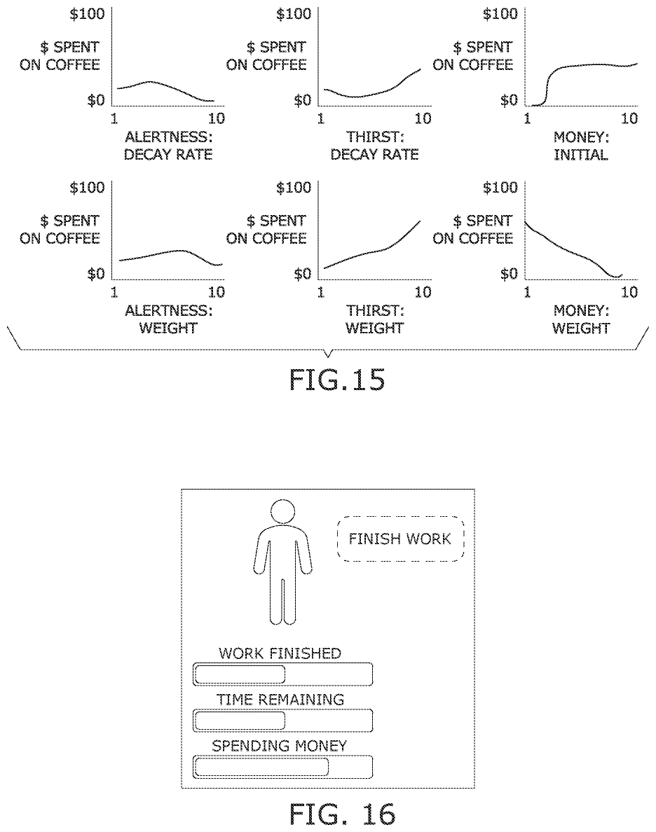

FIG. 15 is a schematic view of graphed results provided by the results feedback engine 50. What do the results say? Well the average Actor spent around $3 per day on your coffee invention, but the average is heavily biased. Your target market is Actors who: 1) Highly value not being thirsty; 2) Can spend at least $5 per day comfortably; and/or 3) only need to be moderately alert. Within the model, the energy drink can be a competitor in the coffee maker market model.

FIG. 16 is a schematic view of generic competitor function. Within the model, actors are provided with one or more generic competitor functions. The generic competitor function can always be chosen and can be used to satisfy all desires, while costing all the available time and money if used continuously. The generic competitor functions are generated automatically by the simulation engine 40, they are not editable. In the example shown, the generic Finish Work function satisfies the Work Desire using all the Time remaining.

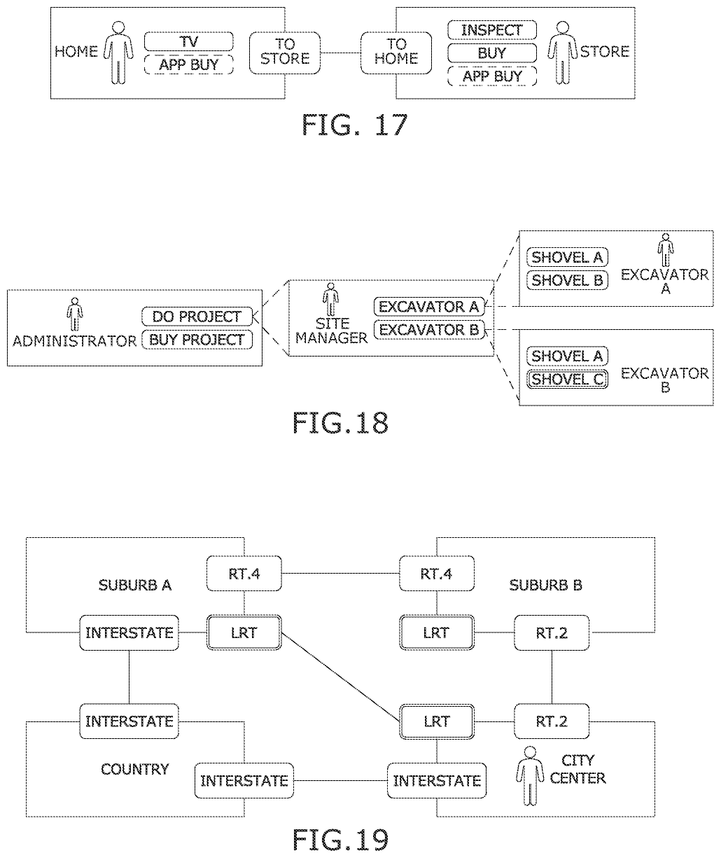

FIG. 17 is a schematic view of decision model for an app-based purchasing model. In this example, the invention is an App that allows the actor to buy a product that can also be bought at a store. In the model of the invention, the app allows the customer to buy a product at any time. The customer must choose to go to the store and buy it or use the app. Going to the store takes time and money, but allows an opportunity for an Inspection of the product which may increase desire for the product. The invention changes WHEN a certain function (Buy) is available, and this alone can have impacts that can be simulated in the simulation engine 40.

FIG. 18 is a schematic view of decision model elements for an excavator shovel. This model simulates the whole value chain with independent Actors. The Actor running Excavator B must see value in the new shovel, but that only provides value if the Site manager sees enough value to choose Excavator B, and the Administrator to see value in the whole project.

FIG. 19 is a schematic view of decision model for a light rail transit (LRT) system. In this model the different routes available to the actor (with corresponding times and costs) are represented. After each decision, the actor is randomly assigned a goal to go to another location. They then choose which method best meets their desires.

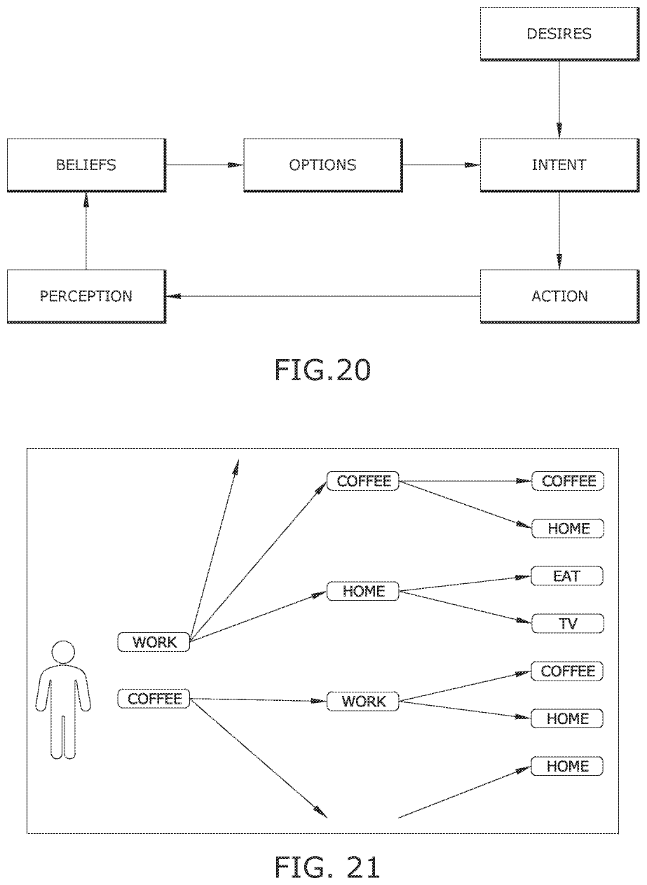

FIG. 20 is a schematic view of a belief-desire-intent (BDI) model. In the BDI model, Beliefs inform the actors opinion of each option. Desires define what the actor would like to achieve, while intent represents what option the actor will take. The standard BDI model selects actions to perform based on which actions satisfy the actor's desires. The model defines that Actor's desires and Options in the decision space.

FIG. 21 is a schematic view of a larger decision tree model in which each decision creates a tree of possibilities. Larger models don't necessarily have smaller trees. Functions can be run more than once, depending upon sequence of a prior decision. Larger models simply have more varied options.

As will be appreciated from the present disclosure, the underlying methods used can apply to any field that is process oriented. For example it may be used to simulate an assembly line or a software development cycle. The present invention provides a standard model format which makes it easy to share descriptions of an item or process. This model format can be used by a cloud-based sharing service to allow inventors to compare models and pitch their idea to investors.

The system of the present invention may include at least one computer with a user interface. The computer may include any computer including, but not limited to, a desktop, laptop, and smart device, such as, a tablet and smart phone. The computer includes a program product including a machine-readable program code for causing, when executed, the computer to perform steps. The program product may include software which may either be loaded onto the computer or accessed by the computer. The loaded software may include an application on a smart device. The software may be accessed by the computer using a web browser. The computer may access the software via the web browser using the internet, extranet, intranet, host server, internet cloud and the like.

The computer-based data processing system and method described above is for purposes of example only, and may be implemented in any type of computer system or programming or processing environment, or in a computer program, alone or in conjunction with hardware. The present invention may also be implemented in software stored on a non-transitory computer-readable medium and executed as a computer program on a general purpose or special purpose computer. For clarity, only those aspects of the system germane to the invention are described, and product details well known in the art are omitted. For the same reason, the computer hardware is not described in further detail. It should thus be understood that the invention is not limited to any specific computer language, program, or computer. It is further contemplated that the present invention may be run on a stand-alone computer system, or may be run from a server computer system that can be accessed by a plurality of client computer systems interconnected over an intranet network, or that is accessible to clients over the Internet. In addition, many embodiments of the present invention have application to a wide range of industries. To the extent the present application discloses a system, the method implemented by that system, as well as software stored on a computer-readable medium and executed as a computer program to perform the method on a general purpose or special purpose computer, are within the scope of the present invention. Further, to the extent the present application discloses a method, a system of apparatuses configured to implement the method are within the scope of the present invention.

It should be understood, of course, that the foregoing relates to exemplary embodiments of the invention and that modifications may be made without departing from the spirit and scope of the invention as set forth in the following claims.

What is claimed is:

1. A system for simulating attributes of an invention, comprising:
a model builder engine configured with a plurality of user controls to input a plurality of simulation parameters to define a model of the invention;
a simulation engine configured to dynamically test the model in a simulation against a plurality of simulated actors in a virtual world according to the plurality of simulation parameters defined in the model of the invention; and
a results engine configured to processes a result of the simulation and extracts useful data for displaying one or more attributes of the invention.

2. The system of claim 1, further comprising:
a guidance engine configured to provide a feedback to a user on one or more qualities of the model to set one or more of the plurality of simulation parameters defining the model of the invention.

3. The system of claim 2, the guidance engine further comprising:
an actor definition control comprising a selector for choosing one or more of a plurality of preset actors defined according to a plurality of predefined demographic groups, specifying a target user of the invention.

4. The system of claim 3, wherein the plurality of predefined demographic groups are specified according to one or more of a geographic location, a gender, an income, and an age.

5. The system of claim 4, wherein the simulation steps the one or more of the plurality of preset actors through a decision model within the model.

6. The system of claim 2, the guidance engine further comprises:
a quality summary page configured to provide the user a rating of each of the model, an actor selection, and the plurality of simulation parameters.

7. The system of claim 6, further comprising:
one or more hints for improving a performance of one or more of the model, an actor selection, and the plurality of simulation parameters.

8. The system of claim 1, wherein the simulation engine processes a passive simulation in which the attributes of the invention processed by the simulation are compared with the simulation in an absence of the invention.

9. The system of claim 1, wherein the simulation engine processes an active simulation in which the attributes of the invention processed by the simulation are compared with an actor option to utilize the invention or a competitor invention.

10. The system of claim 1, wherein the model builder engine further comprises:
a plurality of controls operable by a user to define a function, an item, a relation, and a space.

11. The system of claim 1, wherein a control editor
the results engine may produce a display indicating a number of simulants who use the invention; one or more common traits of those who use the invention; and one or more most-used competitors of the invention.
